(19) United States
(12) Patent Application Publication
(10) Pub. No.: US 2007/0148963 A1
(43) Pub. Date: Jun. 28, 2007

(54) Semiconductor devices incorporating carbon nanotubes and composites thereof

(75) Inventors: Philip Ching-Ho Chan, Hong Kong (CN); Min Zhang, Hong Kong (CN); Xiao Huo, Hong Kong (CN)

Correspondence Address: HESLIN ROTHENBERG FARLEY & MESITI PC, 5 COLUMBIA CIRCLE, ALBANY, NY, 12203, US

(73) Assignee: The Hong Kong University of Science and Technology, Hong Kong (CN)

(21) Appl. No.: 11/318,974

(22) Filed: Dec. 27, 2005

(51) Int. Cl. H01L 21/4763

(52) U.S. Cl. 438/637; 257/E51.04; 977/742

(57) ABSTRACT

Methods of utilizing carbon nanotubes or composites thereof as hole plugs in vias or in contact holes for connecting conductive layers in integrated circuits are disclosed. Integrated circuits and integrated circuit layers formed by the methods are also disclosed.

### FIELD OF INVENTION

The present invention relates to semiconductor devices and methods of forming the same. More particularly the invention relates to methods of utilizing carbon nanotubes or composites thereof as hole plugs in vias or in contact holes for connecting conductive layers in integrated circuits.

### BACKGROUND

Multiple layers of metal are used to connect semiconductor devices in integrated circuits (ICs). “Via” plugs and “contact” plugs were introduced to counter problems experienced with the scaling down in size of integrated circuits. Vias are used to connect different conductive layers, normally metal layers whereas contacts are used to provide the connection between a semiconductor layer and the first conductive layers. Instead of using the next conductive layer to fill a contact directly, contacts or vias are filled and planarized before the next conductive layer is deposited. Tungsten (W) is commonly used in a contact plug to connect the first metal layer and the silicon substrate, and copper (Cu) is commonly used as via plug material to connect different metal layers.

The size of integrated circuits is rapidly decreasing, and as a result contacts and vias need to be scaled accordingly. Contacts and vias are usually the smallest and most abundant features in an integrated circuit, with the performance and yield of the integrated circuit depending heavily on the robustness of the contact and via technology. If the performance of contacts and vias do not improve with the ever-decreasing size of integrated circuits, they have the potential to become the “bottleneck” in a circuit's performance.

Conventional copper vias are susceptible to problems related to electro-migration, leading to electro-migration resistance or even open circuits. In addition, to have a copper plug one must etch a silicon dioxide trench having a predetermined aspect ratio and then fill it with copper. With the decreasing size of integrated circuits, both etching and filling steps will become increasingly difficult to perform accurately.

It is an object of the invention to provide improved or alternative integrated circuits that overcome the problems associated with the prior art.

### SUMMARY OF THE INVENTION

In one aspect the invention broadly describes a method of forming an integrated circuit layer comprising the following steps: depositing an insulating layer on a first conductive layer of an integrated circuit;
patterning the insulating layer to form contact and/or via holes;
forming carbon nanotubes in the contact and/or via holes;
depositing a second conductive layer over the insulating layer;
   wherein a catalyst for the formation of carbon nanotubes is present on at least a portion of the first conductive layer before the insulating layer has been deposited on the first conductive layer.

In a further aspect the invention broadly describes a method of forming an integrated circuit layer comprising the following steps:
depositing a catalyst layer on a first conductive layer;
depositing an insulating layer on the catalyst layer;
patterning the insulating layer with holes thereby exposing the catalyst layer in the holes;
forming carbon nanotubes in the holes;
depositing a second conductive layer over the insulating layer.

In a preferred embodiment, the carbon nanotubes are formed by chemical vapour deposition.

Preferably the insulating layer is planarised or the carbon nanotubes are subjected to a plasma treatment prior to the deposition of the second conductive layer. More preferably the insulating layer is subjected to a chemical mechanical polish prior to the deposition of the second conductive layer.

Preferably the catalyst is a metal catalyst. While the specific catalyst is dependent on the method used to form the carbon nanotubes, particularly preferred catalysts are iron (Fe), cobalt (Co), nickel (Ni), ruthenium (Ru), gold (Au), platinum (Pt), and compounds thereof.

In a further aspect the invention broadly describes a method of forming an integrated circuit layer comprising the following steps:
depositing an insulating layer on a first conductive layer of an integrated circuit;
patterning the insulating layer to form contact and/or via holes;
forming carbon nanotube/metal composites in the contact and/or via holes;
depositing a second conductive layer over the insulating layer;
wherein a catalyst for the formation of carbon nanotube/metal composites is present on at least a portion of the first conductive layer before the insulating layer has been deposited on the first conductive layer.

In yet a further aspect, the invention broadly describes a method of forming an integrated circuit layer comprising the following steps:
depositing a catalyst layer on a first conductive layer;
depositing an insulating layer on the catalyst layer;
patterning the insulating layer with holes thereby exposing the catalyst layer in the holes;
forming carbon nanotube/metal composites in the holes;
depositing a second conductive layer over the insulating layer.
wherein a catalyst for the formation of carbon nanotube/metal composites is present on at least a portion of the first conductive layer before the insulating layer has been deposited on the first conductive layer.

The invention also comprises integrated circuit layers formed by the above methods.

### BRIEF DESCRIPTION OF THE DRAWINGS

The above objects and advantages of the present invention will become more apparent by describing in detail a preferred embodiment thereof with reference to the attached drawings in which:

FIG. 1 illustrates a cross sectional view of an integrated circuit structure using carbon nanotube contact plugs and carbon nanotube via plugs.

FIG. 2 illustrates a cross sectional view of an integrated circuit structure after the first contact holes opening.

FIG. 3 illustrates a cross sectional view of an integrated circuit structure after the first carbon nanotube plugs formation.

FIG. 4 illustrates a cross sectional view of an integrated circuit structure after the first via holes opening.

FIG. 5 illustrates a cross sectional view of an integrated circuit structure after the second metal layer patterning.

FIG. 6 illustrates a cross sectional view of an integrated circuit structure using CNT-metal composite as contact plugs and via plugs.

FIG. 7 illustrates a cross sectional view of an integrated circuit structure after the contact holes opening.

FIG. 8 illustrates a cross sectional view of an integrated circuit structure after the first carbon nanotube growth.

FIG. 9 illustrates a cross sectional view of an integrated circuit structure after the first CNT-metal composite contact plug formation.

FIG. 10 illustrates a cross sectional view of an integrated circuit structure after the first via holes opening.

FIG. 11 illustrates a cross sectional view of an integrated circuit structure after the second metal layer patterning.

FIG. 12A to 12D illustrate the traditional process scheme to form the CNT vias or contacts.

FIG. 13A to 13D illustrate a new process scheme to form the CNT via or contact.

FIG. 14A to 14E illustrates an alternative method for forming a CNT-metal composite contact/via plug.

### DETAILED DESCRIPTION OF THE INVENTION

The present invention will now be described more fully with reference to the accompanying drawings, in which a preferred embodiment of the invention is shown. This invention may, however, be embodied in many different forms and should not be construed as being limited to the embodiment set forth herein. These embodiments are described in sufficient detail to enable those of ordinary skill in the art to practice the invention.

Disadvantages with producing smaller integrated circuits have recently been addressed by using carbon nanotubes (CNTs) as vias since CNTs have larger electro-migration tolerance and can sustain higher current density (>10⁹ A/cm²). CNTs have high thermal conductivity (>3000 W/m·K), which potentially alleviates thermal dissipation problems. CNTs in via and contact plugs also exhibit low resistance (resistivity of 10⁻⁶ Ω·cm) even in scaled-down vias. In addition, CNTs are strong fibers with good mechanical strength, and have the highest Young's Modulus of all known materials presently known (Y˜1.2 Tpa), increasing the reliability of integrated circuits.

In the present invention, CNT and/or CNT-metal composites replace existing tungsten contact plugs and copper via plugs. Carbon nanotubes allow a huge electrical current density owing to ballistic electron transport. Small diameter and large length of the carbon nanotubes make the scaling much easier. However, the large contact resistance between carbon nanotubes and metal can be a hurdle for using carbon nanotubes as contact via or interconnect materials. The benefit of high current density capability of carbon nanotubes can be entirely covered by this large contact resistance. A CNT-metal composite can provide a tradeoff between current density capability and contact resistance. Since this composite material can provide increased current density capability with reasonable contact resistance, it can be a practical way to use carbon nanotubes as contact via plug and interconnect in integrated circuit.

The catalysts used in the present invention may would be known to a person skilled in the art. When selecting a catalyst, the skilled artisan should select a catalyst that is able to agglomerate to the grain, the size of which dictates the diameter of the CNTs. Preferred catalysts are selected from iron, cobalt, nickel, ruthenium, gold, and platinum.

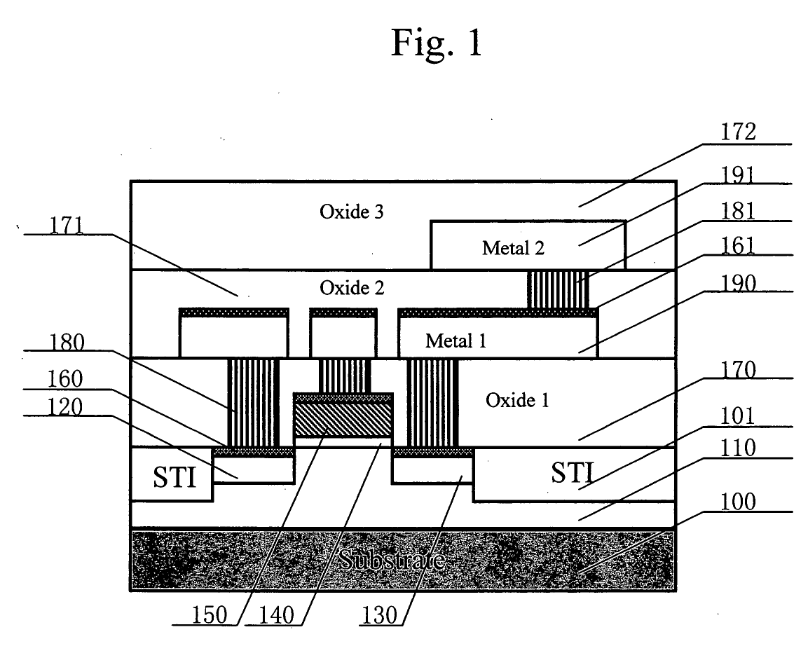

FIG. 1 shows a cross sectional view of an integrated circuit structure using carbon nanotube contacts as via plugs and contact plugs. The invention can be applied to a metal oxide semiconductor (MOS) device and circuit, any of a NMOS, a PMOS, or a CMOS. Without loss of generality, a bulk silicon based NMOS is used for illustration with reference to FIG. 1. The NMOS transistor is fabricated in P substrate or P well 110 on a substrate 100 with N+ source 120 and N+ drain 130, silicon dioxide 140 as gate dielectric, and an N+ polysilicon gate 150. The transistor is isolated from other transistors by insulating region 101. The transistor is provided with progress of metal catalyst 160. The transistor is separated from a first metal layer 190 by oxide film 170. Carbon nanotubes are used as contact plugs 180 to connect respective the transistor source, drain and gate to first metal layer 190. Another carbon nanotubes contact plug 181 is used to connect the first metal layer 190 to a second metal layer 191. A second catalyst layer 161 is used for the carbon nanotubes plug 181 growth. Dielectric film 171 is used to separate the first metal layer 190 and the second metal layer 191. Depending on the technology, a different number of multi metal layers can be used for the integrated circuits. This invention can be applied to any integrated devices and circuits with multiple metal layer interconnections.

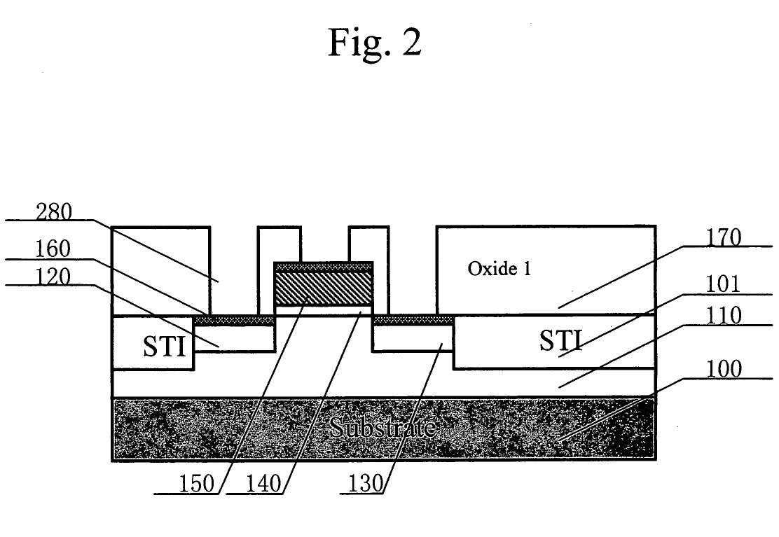

FIG. 2 illustrates a cross sectional view of an NMOS device after contact via holes 280 opening. The formation of such a structure would be well known to those of ordinary skill in the art. The catalyst layer 160 can be Ni, Fe, Co, or other suitable metals or alloys, with the catalyst layer applied using a method such as physical vapor deposition (PVD) (e.g. sputtering or evaporation). Solution coating is another method for layering the catalyst on the conductive layer. A catalyst is coated on the surface where the CNTs are to be grown, and subsequently evaporated and baked. A photoresistant layer may be used if the catalyst layer is to be patterned. This layer will act as the catalyst for the carbon nanotube plug 180 growth.

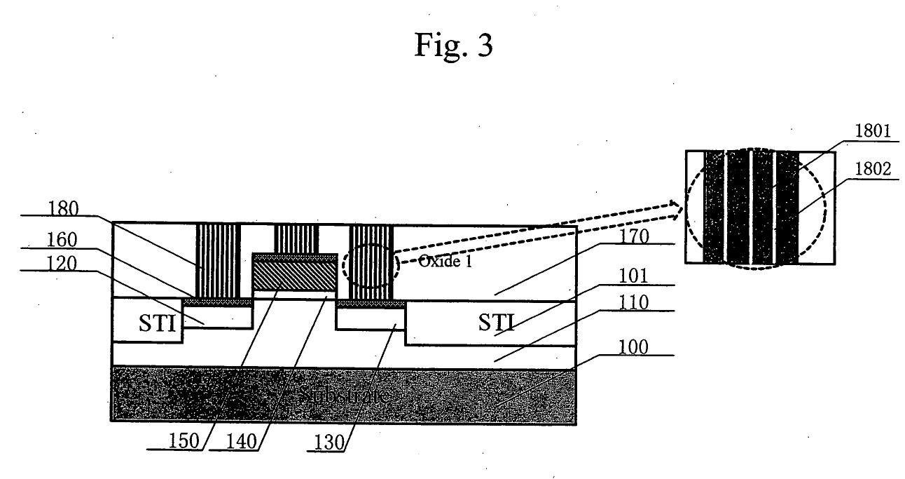

Thereafter, the carbon nanotube plug 180 is vertically grown by using a chemical vapor deposition (CVD) process, such as plasma-enhanced CVD (PECVD), microwave CVD (MWCVD), hot-filament CVD (HFCVD), bias-enhanced CVD, or thermal CVD. The process gas for carbon nanotube growth can be hydrocarbon such as methane, ethane, ethylene, acetylene, xylene, benzene, other suitable hydrocarbon, a mixture of the hydrocarbon and hydrogen, a mixture of the hydrocarbon and argon, or a mixture of the hydrocarbon and the other suitable diluting gas. The process temperature can range from 450 to 1000 degrees centigrade. The process can take from 1 minute to 15 minutes, or possibly longer according to different length requirements. After the carbon nanotubes growth, a chemical mechanical polish (CMP) step or a plasma treatment can be performed on the device surface to prepare a flat surface and expose the CNTs for the first metal layer 190 deposition. The structure after the CMP process is shown in FIG. 3. In the detailed view of the plug in FIG. 3 180, 1801 show the CNTs and 1802 the spacing between CNTs. Optimizing the CNT growth recipe can reduce the space 1802 between CNTs 1801.

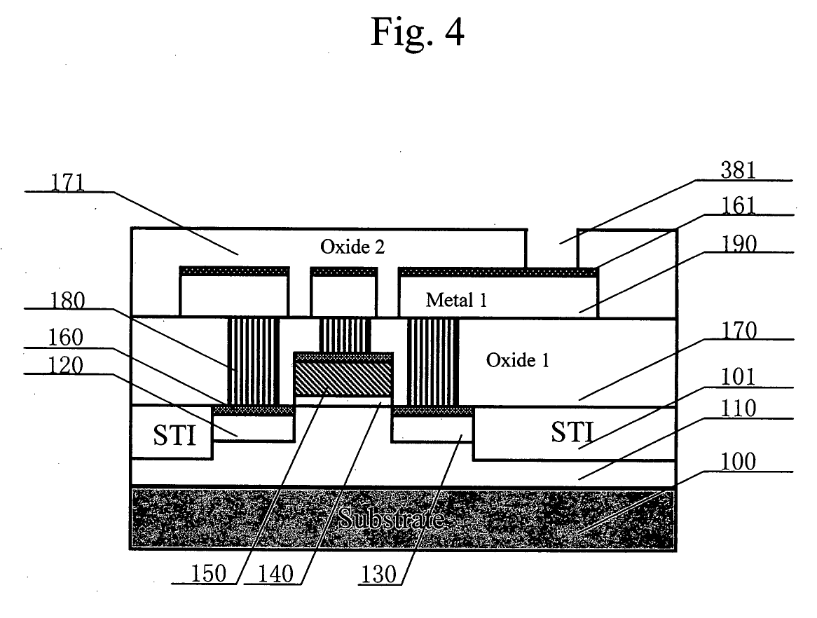

The first metal layer 190 (which can be aluminum, copper, polysilicon, alloy or any other suitable conductive material) is deposited on the surface. The first metal layer 190 is then patterned by using any suitable process, for example, plasma etch which is well known to those of ordinary skill in the art. The second catalyst layer 161 is deposited on the first metal layer 190. The second catalyst layer can be Ni, Fe, Co, or other suitable metals or other suitable materials. The second catalyst layer 161 is then patterned by using an etching process or liftoff process, which is well known by those of ordinary skill in the art. Alternatively, the first metal layer 190 and the second catalyst layer 161 can be patterned simultaneously by using an etching process or liftoff process, which are both well known by those of ordinary skill in the art. After the catalyst patterning, a second dielectric film 171, such as silicon oxide layer, is deposited to cover the first metal layer 190 and catalyst layer 161. Then a chemical mechanical polishing step is performed for second dielectric layer 171. Contact via holes 381 are opened using a well-known etching process, for example, plasma dry etching. FIG. 4 illustrates the device after formation of contact via holes 381.

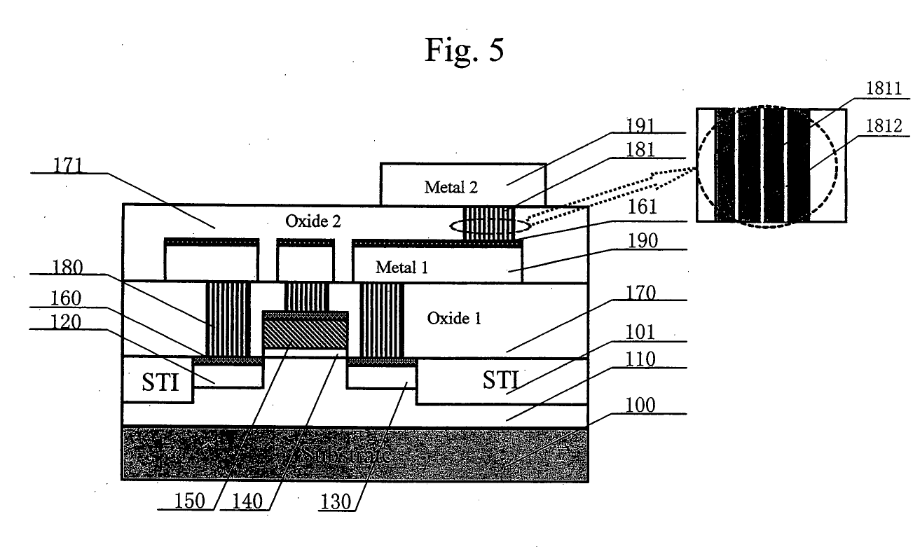

A carbon nanotube plug 181 is vertically grown by using same process as that used for growth of carbon nanotubes plug 180. For the details of the plug 181, shown in the exploded part of FIG. 5, 1811 are the CNTs and 1812 shows the spacing between CNTs. Optimizing the CNT growth recipe can reduce the spacer 1812, and the CMP step or the plasma treatment can be carried out after growth of carbon nanotubes plug 181. The second metal layer 191 then is deposited and patterned using a well-known metal etching process or liftoff process, referring to FIG. 5. The third dielectric film 172 shown in FIG. 1, which is an oxide film in MOS technology, is deposited on the second metal layer 191. In this illustration, the third dielectric film 172 is used as a passivation layer. For technology with more than two metal layers, this layer can be used to separate the second metal layer from a third metal layer, in which this invention can still be used for via plugs between these two metal layers. This invention can be extended to be used between any two conductive layers.

In FIG. 5, for either contact plugs 180 and via plugs 181, each can be a single single-walled CNT, a single multi-walled CNT, an array of multiple single-walled CNTs, or an array of multiple multi-walled CNTs. The spacing between CNTs and the spacing between CNTs and the neighboring insulation layer 170 and 171, labeled as 1802 and 1812, can be filled with metal, other conductive material, silicon dioxide, or left with air in the layer.

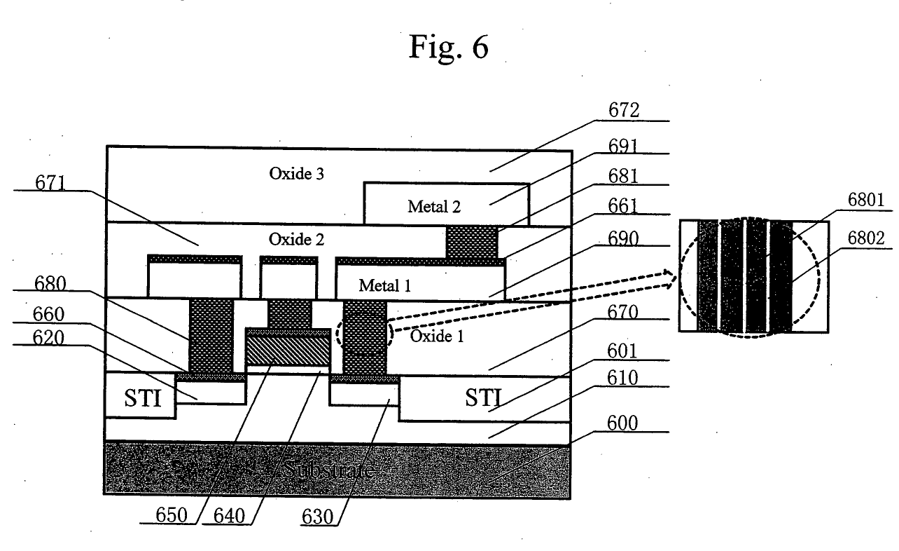

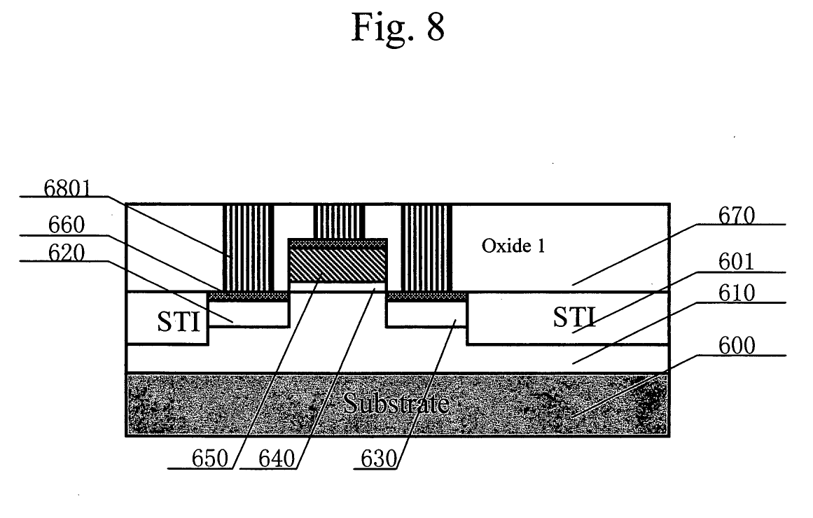

FIGS. 6 to 11 demonstrate the process of forming a CNT-metal composite as a contact or a via plug. The process is similar to the contact or via plug using pure carbon nanotubes as contact or via plugs. FIG. 6 shows a cross sectional view of an integrated circuit structure using CNT-metal composite plugs. The invention can be applied to a metal oxide semiconductor (MOS) device, either a NMOS, a PMOS or a CMOS device. Without loss of generality, a bulk silicon based NMOS is used for illustration with reference to FIG. 6. The NMOS transistor is fabricated in P substrate or P well 610 on a substrate 600 with N+ source 620 and N+ drain 630, a silicon dioxide 640 as gate dielectric, an N+ polysilicon gate 650. The transistor is isolated from other transistors by insulating region 601. The transistor has metal catalyst 660. The transistor is separated with the first metal layer by an oxide film 670. CNT-metal composite is used as the contact plug 680 to connect the transistor source, drain, and gate to the first metal layer 690. As indicated in FIG. 6, the CNT-metal composite 680 comprises of carbon nanotubes 6801 and metal 6802. Another CNT-metal contact plug 681 is used to connect the first metal layer 690 to the second metal layer 691. This CNT-metal composite 681 is comprises carbon nanotubes 6811 and metal 6812. The second catalyst layer 661 can be used for the carbon nanotube growth in plug 681 growth. Dielectric film 671 is used to separate the first metal layer 690 and the second metal layer 691. The metal 6802 and metal 690 may be the same or different metals; similarly the metal 6812 and metal 691 can be the same or different metals. Depending on the technology, different numbers of multi metal layers can be used for the integrated circuits. This invention can be applied to any integrated devices and circuits with multiple metal layer interconnections.

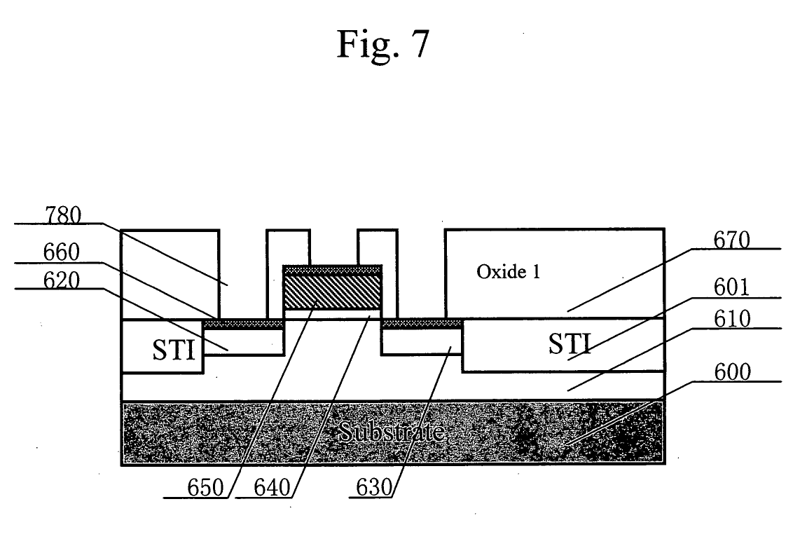

FIG. 7 illustrates a cross sectional view of an NMOS device after the opening of the contact hole 780. The formation of such a structure is well known by those of ordinary skill in the art. The catalyst layer 660 can be Ni, Co, Fe, or an other suitable metal or alloys, and can be formed using PVD or solutions. This layer acts as a catalyst for the growth of the carbon nanotubes 6801 in the plug 680.

Carbon nanotubes 6801 are then vertically grown in the plug, preferably using a chemical vapor deposition (CVD) process. The process gas for carbon nanotube growth can be hydrocarbon such as methane, ethane, ethylene, acetylene, xylene, benzene, other suitable hydrocarbon, a mixture of the hydrocarbon and hydrogen, a mixture of the hydrocarbon and argon, or a mixture of the hydrocarbon and the other suitable diluting gas.

When determining which hydrocarbon is appropriate for use in CVD, a skilled reader would need to consider the following:
The hydrocarbon must have a sufficient proportion of carbon for creating CNTs;
The hydrocarbon must have a suitable thermal decomposition temperature range;
The decomposition of the hydrocarbon should not have many byproducts, as an excess of byproducts decreases the CNT purity; and
The hydrocarbon selected must be paired with a suitable catalyst.

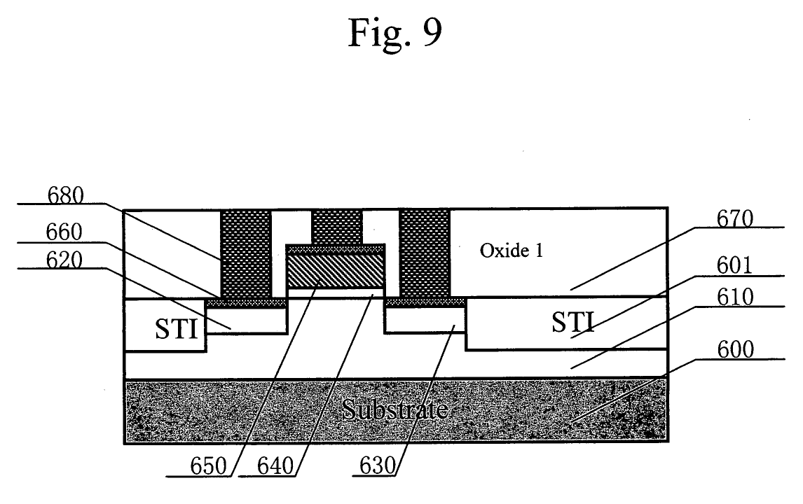

The process temperature can range from 450 to 1000 degrees centigrade. The process can take from 1 minute to 15 minutes, or conceivably longer depending on the length of CNT required. After the carbon nanotubes growth, a planarization step or a plasma treatment can be performed for the device surface to flatten the surface for the metal 6802 formation as shown in FIG. 6. The metal 6802 can be formed in the holes and on the surface using well-known techniques such as PVD. The metal can be aluminum, copper, titanium, or any pure metal or alloy. A high temperature process is needed for the CNTs and the filled metal to form a CNT-metal composite. Depending on the metal used, the temperature can range from 400 to 1500 degrees centigrade. A CMP process may be used to further planarize the surface. A structure after undergoing the CMP process is shown in FIG. 9.

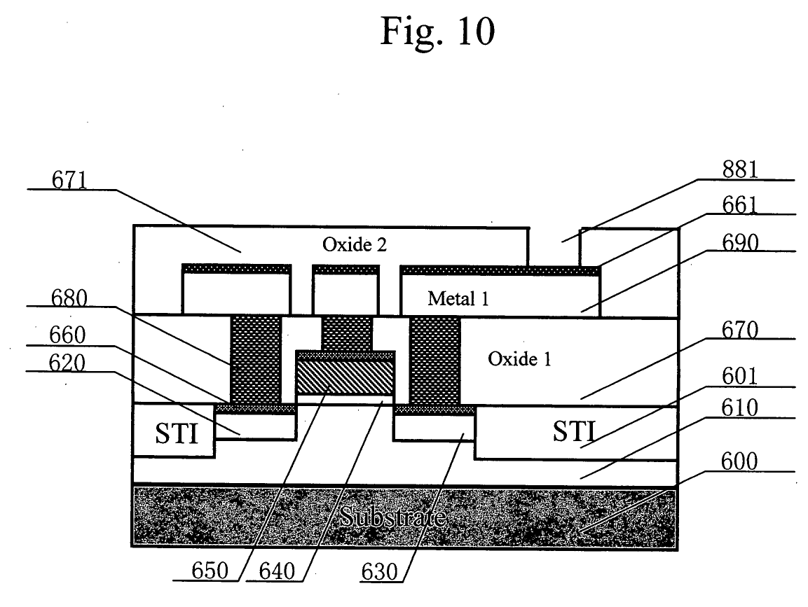

The first metal layer 690 (which can be aluminum, copper, or any other pure metal or alloy materials) is deposited on the surface. The second catalyst layer 661 is then deposited on the first metal layer 690. The second catalyst layer can be Ni, Co, Fe, Al or other alloy materials. The first metal layer 690 and the second catalyst layer 661 are then patterned by using an etching process, for example, plasma etching. After the patterning, a second dielectric film 671, such as silicon oxide layer, is deposited on the first metal layer. Then a chemical mechanical polishing step is performed for the second dielectric layer 671. Via holes 881 are opened using a well-known etching processes. FIG. 10 illustrates the device after the via holes 881 formation.

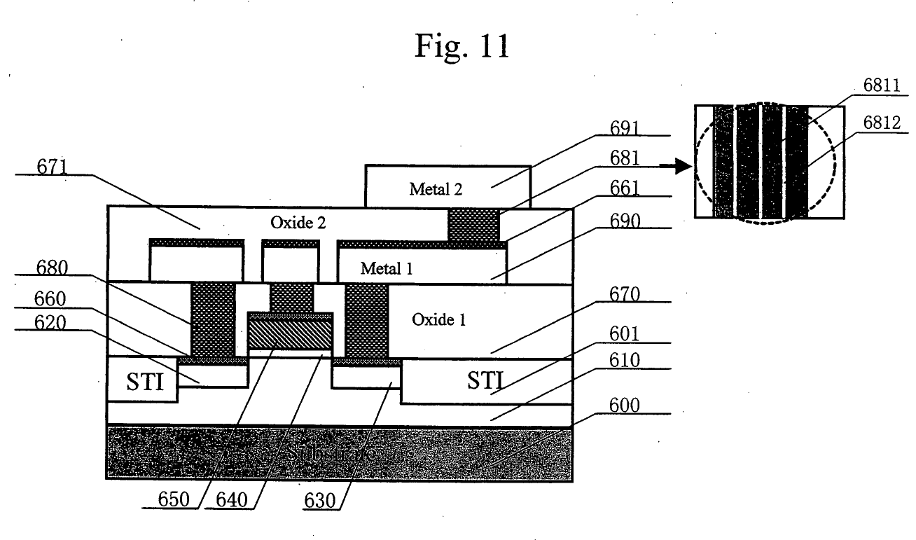

Carbon nanotubes plug 6811 are vertically grown using the same process as used for carbon nanotube plug 6801 growth. A CMP step or a plasma treatment may be performed after the growth of the carbon nanotube plug 6811. Metal 6812 can be deposited in 881 and planarized. The second metal layer 691 is then deposited and patterned using known metal etching processes (FIG. 11). The third dielectric film 672 in FIG. 6, is deposited on the second metal layer 691. In this embodiment, the third dielectric film 672 is used as a passivation layer. For circuits with more than two metal layers, this layer can be used to separate the second metal layer with the third metal layer, in which this invention can still be taken for via plugs between these two metal layers. This invention can be extended to be used between any two conductive layers.

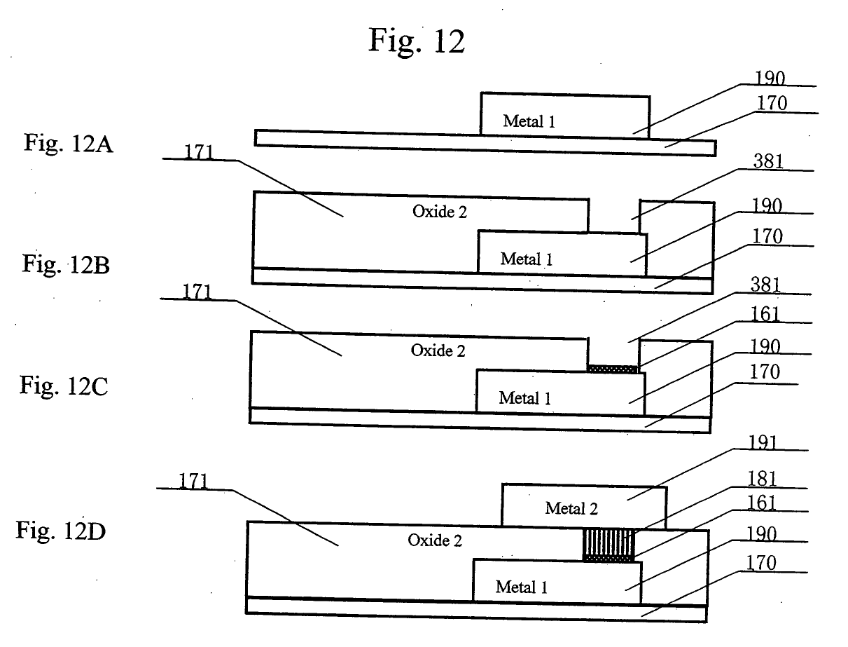

FIGS. 12 and 13 illustrate two different processes for forming the contact hole plug or via hole plug. Without loss of generality, via plug formation is illustrated in FIG. 12. After patterning the metal 190, the oxide 171 is formed. The via hole 381 is then opened to the oxide 171. The catalyst layer 161 is formed in the via hole (FIG. 12C). The CNTs are grown in the via hole area by a CVD process. A CMP or a plasma treatment can be used to planarize and clean the surface. Finally, the upper metal layer 191 is formed and patterned (FIG. 12D).

FIG. 13 illustrates an alternative embodiment, in this case via plug formation. After forming the metal 190, a catalyst layer 161 is formed on the surface. The metal 190 and the catalyst 161 can be patterned using a same lithograph step before the oxide 171 is deposited. This method avoids the difficulty to deposit the catalyst in the small via holes and it also avoids the difficulty for the alignment between the via holes and the catalyst, shown in FIG. 12. The via hole 381 is then opened to the oxide 171, and the CNTs are grown on the exposed catalyst area by a suitable CVD process, to form the via plug 181. A CMP or a plasma treatment can be used to planarize and clean the surface, as shown in FIG. 13(C). The upper metal layer 191 is then formed and patterned (FIG. 13D).

The two schemes illustrated in FIGS. 12 and 13 can also be used for CNT contact plug 180 formation, and also for CNT-metal composite via plug 680 and CNT-metal composite contact 681 formation.

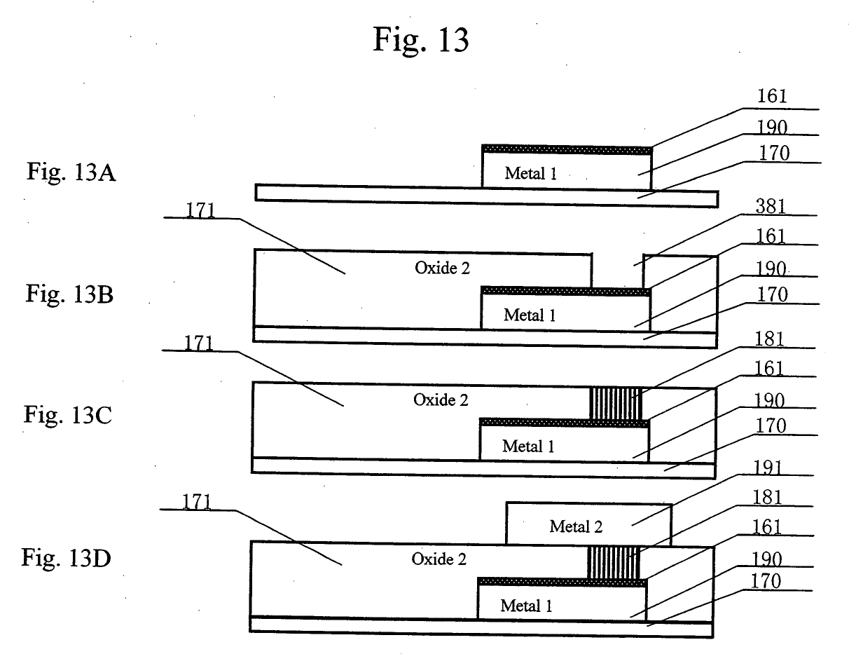

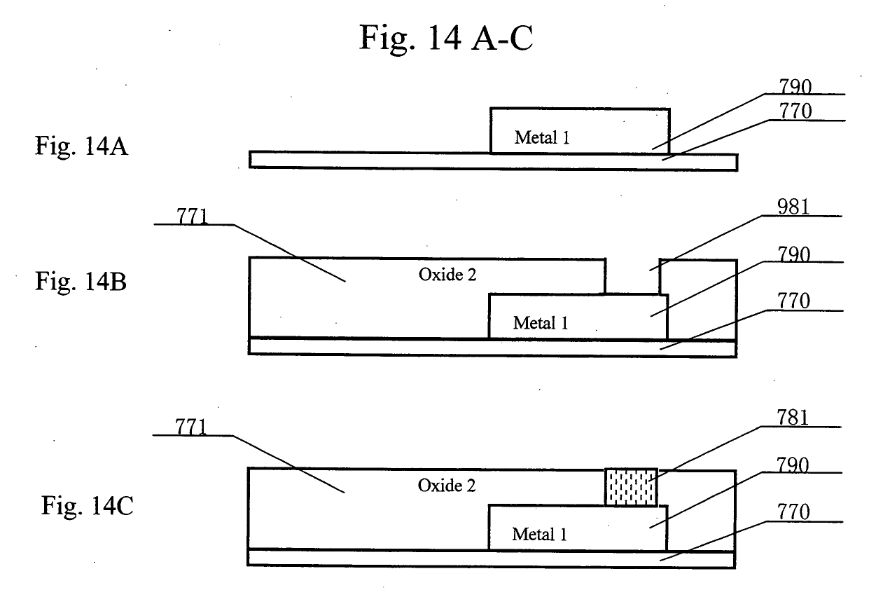

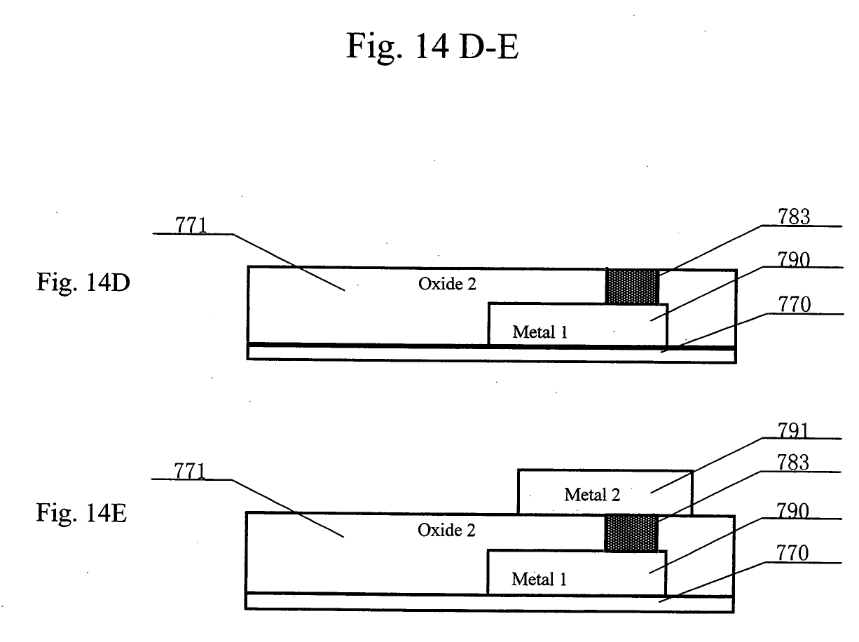

Another method for CNT/metal composite via plug formation is illustrated in FIG. 14. In this method, the CNTs are grown first using techniques known in the art, such as CVD, laser ablation, or are discharge. The CNTs are then purified and dispersed in a suitable solvent (such as 1,2-dichloroethane). The via hole 981 is opened to the oxide 771 and the purified CNTs 781 are deposited into the via hole as shown in FIG. 14C. Metal is deposited in the hole using known methods (e.g. liftoff or PVD). Suitable metals are aluminum, copper and titanium, or alloys of those metals. The CNTs and the metal are subjected to high temperatures to form a CNT-metal composite 783 in the via hole. Finally, the upper metal 791 is formed and patterned. This method can be applied for the formation of a CNT-metal composite contact plug 680 and CNT-metal composite via plug 681.

Although the invention has been described in terms of several embodiments, those skilled in the art will recognize that the invention is not limited to the embodiments described, but can be practiced with modification and alternation without departing from the scope and spirit of the invention as defined by the following claims.

1-39. (canceled)

40. A method of forming an integrated circuit layer comprising the following steps:
depositing an insulating layer on a first conductive layer of an integrated circuit;
patterning the insulating layer to form contact and/or via holes;
forming carbon nanotubes in the contact and/or via holes;
depositing a second conductive layer over the insulating layer;
wherein a catalyst for the formation of carbon nanotubes is present on at least a portion of the first conductive layer before the insulating layer has been deposited on the first conductive layer.

41. A method of forming an integrated circuit layer comprising the following steps:
depositing a catalyst layer on a first conductive layer;
depositing an insulating layer on the catalyst layer;
patterning the insulating layer with holes thereby exposing the catalyst layer in the holes;
forming carbon nanotubes in the holes;
depositing a second conductive layer over the insulating layer.

42. A method according to claim 40 wherein the carbon nanotubes are formed by chemical vapor deposition.

43. A method according to claim 40 wherein the insulating layer is planarized prior to the deposition of the second conductive layer.

44. A method according to claim 43 wherein the insulating layer is subjected to a chemical mechanical polish prior to the deposition of the second conductive layer.

45. A method according to claim 40 wherein the catalyst is deposited on the first conductive layer prior to the deposition of the insulating layer on the first conductive layer.

46. A method according to claim 41 wherein the catalyst is deposited on the first conductive layer using a technique selected from physical vapor deposition and solution coating.

47. A method according to claim 40 wherein the catalyst is a metal catalyst.

48. A method according to claim 47 wherein the catalyst is iron, cobalt, nickel, ruthenium, gold, platinum, or compounds thereof.

49. A method according to claim 40 wherein the carbon nanotubes are formed by chemical vapor deposition (including plasma-enhanced CVD (PECVD), microwave CVD (MWCVD), hot-filament CVD (HFCVD), bias-enhanced CVD, thermal CVD etc.), laser ablation, or arc discharge.

50. A method according to claim 49 wherein the carbon nanotubes are formed by plasma enhanced chemical vapor deposition.

51. A method according to claim 49 wherein the chemical vapor deposition uses a gas selected from methane, ethane, ethylene, acetylene, xylene, and benzene.

52. A method according to claim 51 wherein the gas is mixed with hydrogen or argon.

53. A method according to claim 40 wherein the insulating layer is planarized after the formation of the carbon nanotubes.

54. A method according to claim 40 wherein the carbon nanotubes are treated with a plasma process after the formation of the carbon nanotubes.

55. A method according to claim 53 wherein the insulating layer is subjected to a chemical mechanical polishing process.

56. A method according to claim 40 wherein the first conductive layer and second conductive layer are independently selected from aluminum, copper, and polysilicon.

57. A method according to claim 40 wherein the catalyst layer and the metal layer underneath are patterned at the same lithography step before depositing and pattering the upper insulation layer.

58. An integrated circuit layer made by a method according to claim 40.

59. An integrated circuit comprising an integrated circuit layer made by a method according to claim 40.

60. A method of forming an integrated circuit layer comprising the following steps:
depositing an insulating layer on a first conductive layer of an integrated circuit;
patterning the insulating layer to form contact and/or via holes;
forming carbon nanotube/metal composites in the contact and/or via holes;
depositing a second conductive layer over the insulating layer;
wherein a catalyst for the formation of carbon nanotube/metal catalyst composites is present on at least a portion of the first conductive layer before the insulating layer has been deposited on the first conductive layer.

61. A method according to claim 60 wherein the carbon nanotube/metal composites are formed by chemical vapor deposition.

62. A method according to claim 60 wherein the insulating layer is planarized prior to the deposition of the second conductive layer.

63. A method according to claim 62 wherein the insulating layer is subjected to a chemical mechanical polish prior to the deposition of the second conductive layer.

64. A method according to claim 60 wherein the catalyst is deposited on the first conductive layer prior to the deposition of the insulating layer on the first conductive layer.

65. A method according to claim 64 wherein the catalyst is deposited on the first conductive layer using a technique selected from physical vapor deposition and solution coating.

66. A method according to claim 60 wherein the catalyst is a metal catalyst.

67. A method according to claim 66 wherein the catalyst is iron, cobalt, nickel, ruthenium, gold, platinum, or compounds thereof.

68. A method according to claim 60 wherein the carbon nanotube/metal composites are formed by chemical vapor deposition (including plasma-enhanced CVD (PECVD), microwave CVD (MWCVD), hot-filament CVD (HFCVD), bias-enhanced CVD, thermal CVD etc.), laser ablation, or arc discharge.

69. A method according to claim 68 wherein the carbon nanotube/metal composites are formed by plasma enhanced chemical vapor deposition.

70. A method according to claim 68 wherein the chemical vapor deposition uses a gas selected from methane, ethane, ethylene, acetylene, xylene, and benzene.

71. A method according to claim 70 wherein the gas is mixed with hydrogen or argon.

72. A method according to claim 60 wherein the insulating layer is planarized after the formation of the carbon nanotube/metal composites.

73. A method according to claim 60 wherein the carbon nanotube/metal composites are treated with a plasma process after their formation.

74. A method according to claim 72 wherein the insulating layer is subjected to a chemical mechanical polishing process.

75. A method according to claim 60 wherein the first conductive layer and second conductive layer are independently selected from aluminum, copper, and polysilicon.

76. A method according to claim 60 wherein the catalyst layer and the metal layer underneath are patterned at the same lithography step before depositing and pattering the upper insulation layer.

77. An integrated circuit layer made by a method according to claim 60.

78. An integrated circuit comprising an integrated circuit layer made by a method according to claim 60.
